(19) United States
(12) Patent Application Publication
(10) Pub. No.: US 2025/0112031 A1
(43) Pub. Date: Apr. 3, 2025

(54) SUBSTRATE PROCESSING APPARATUS, SUBSTRATE PROCESSING SYSTEM, AND CLEANING METHOD

(71) Applicant: Tokyo Electron Limited, Tokyo (JP)

(72) Inventors: Takashi ARAMAKI, Miyagi (JP); Lifu LI, Miyagi (JP)

(73) Assignee: Tokyo Electron Limited, Tokyo (JP)

(21) Appl. No.: 18/980,363

(22) Filed: Dec. 13, 2024

Related U.S. Application Data
(63) Continuation of application No. PCT/JP2023/038415, filed on Oct. 25, 2023.

(30) Foreign Application Priority Data
Oct. 31, 2022 (JP) 2022-174530

(51) Int. Cl. H01J 37/32

(52) U.S. Cl. CPC H01J 37/32862; H01J 37/32091; H01J 37/32568; H01J 37/32642; H01J 37/32724; H01J 2237/022

(57) ABSTRACT

A substrate processing apparatus includes a processing container, a stage, an edge ring, a lifter, and circuitry. The stage has a first mounting surface and a second mounting surface. The edge ring is placed on the second mounting surface. The lifter moves the edge ring with respect to the second mounting surface. Plasma processing of the substrate is performed while the substrate is positioned on the first mounting surface. Further, a first cleaning process is performed in which a first bias RF power is supplied to the stage while the edge ring is separated from the second mounting surface and then a second cleaning process is formed in which a second bias RF power is supplied to the stage while the edge ring is separated from the second mounting surface.

### CROSS-REFERENCE TO RELATED APPLICATIONS

This application is a bypass continuation application of international application No. PCT/JP2023/038415 having an international filing date of Oct. 25, 2023, and designating the United States, the international application being based upon and claiming the benefit of priority from Japanese Patent Application No. 2022-174530, filed on Oct. 31, 2022, the entire contents of each are incorporated herein by reference.

### TECHNICAL FIELD

Various aspects and embodiments of the present disclosure relate to a substrate processing apparatus, a substrate processing system, and a cleaning method.

### BACKGROUND

JP2018-10992A discloses “a focus ring replacing method used for a plasma processing apparatus capable of performing plasma processing on a substrate mounted on a stage provided in a processing chamber and replacing a focus ring mounted on the stage to surround a periphery of the substrate, the focus ring replacing method including: an unloading step of unloading the focus ring from the processing chamber by a transfer apparatus that transfers the focus ring without exposing the processing chamber to the atmosphere; a cleaning step of, after the unloading step, cleaning a surface of the stage on which the focus ring is mounted; and a loading step of, after the cleaning step, loading the focus ring into the processing chamber by the transfer apparatus and mounting the focus ring on the stage, without exposing the processing chamber to the atmosphere”.

### CITATION LIST

### Patent Documents

Patent Document 1: JP2018-10992A

### SUMMARY

The present disclosure provides a substrate processing apparatus, a substrate processing system, and a cleaning method capable of more efficiently removing deposits attached to an edge ring.

According to an aspect of the present disclosure, there is provided a substrate processing apparatus including a processing container, a stage, an edge ring, a lifter, and a controller. The stage is provided in the processing container, and has a first mounting surface on which a substrate is placed and a second mounting surface surrounding an outer periphery of the first mounting surface. The edge ring is configured to be placed on the second mounting surface. The lifter lifts and lowers the edge ring with respect to the second mounting surface. The controller performs a process a), a process b), and a process c). In the process a), the controller performs plasma processing on the substrate placed on the first mounting surface. Further, in the process b), each time the process a) is performed on a predetermined first number of the substrates, the controller controls the lifter to separate the edge ring from the second mounting surface, and performs first cleaning of the inside of the processing container. Further, in the process c), before replacing the edge ring, the controller controls the lifter to separate the edge ring from the second mounting surface, and performs second cleaning of the inside of the processing container.

According to various aspects and embodiments of the present disclosure, it is possible to more efficiently remove deposits attached to the edge ring.

### BRIEF DESCRIPTION OF DRAWINGS

FIG. 1 is a system configuration diagram illustrating an example of a substrate processing system according to one or more embodiments of the present disclosure.

FIG. 2 is a schematic cross-sectional view illustrating an example of a structure of a PM according to the embodiment of the present disclosure.

FIG. 3 is an enlarged cross-sectional view illustrating an example of a structure near an edge of an electrostatic chuck.

FIG. 4 is a flowchart illustrating an example of a substrate processing method.

FIG. 5 is a flowchart illustrating an example of a substrate processing method.

FIG. 6 is a view illustrating an example of a position of an edge ring during cleaning.

FIG. 7 is a view illustrating an example of a process of loading a dummy substrate.

FIG. 8 is a view illustrating an example of a position of an edge ring during cleaning.

FIG. 9 is a view illustrating another example of a process of unloading a dummy substrate and an edge ring.

FIG. 10 is a plan view illustrating an example of a positional relationship between a dummy substrate and an edge ring and a first fork and a second fork.

FIG. 11 is an enlarged cross-sectional view illustrating another example of a structure near an edge of the electrostatic chuck.

FIG. 12 is a view illustrating an example of positions of an edge ring and a cover ring during cleaning.

### DETAILED DESCRIPTION

Hereinafter, embodiments of a substrate processing apparatus, a substrate processing system, and a cleaning method will be described in detail with reference to the drawings. Note that the substrate processing apparatus, the substrate processing system, and the cleaning method disclosed herein are not limited by the following embodiments.

On the other hand, in a case where an edge ring in a processing container is replaced by a transfer apparatus provided in a vacuum transfer apparatus, when reaction by-products (so-called deposits) are attached to the edge ring to be replaced, the deposits may fall into the vacuum transfer apparatus and contaminate the inside of the vacuum transfer apparatus. For this reason, in a case of replacing the edge ring, cleaning of the used edge ring may be performed before the replacement.

However, in a case where there are many deposits attached to the edge ring, the deposits attached to the edge ring may not be completely removed by simply performing the cleaning immediately before the replacement. When the deposits remain on the edge ring, the deposits may fall into the vacuum transfer apparatus and contaminate the inside of the vacuum transfer apparatus.

Therefore, the present disclosure provides a technology capable of more efficiently removing the deposits attached to the edge ring.

### Configuration of Substrate Processing System 50

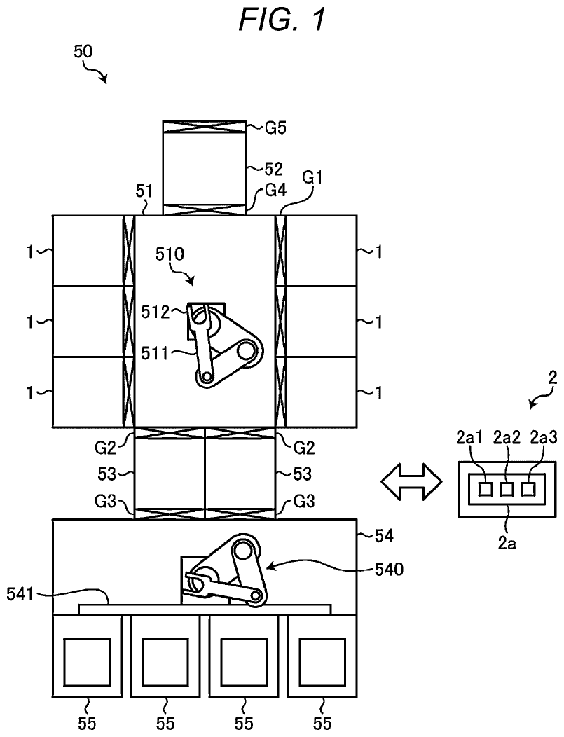

FIG. 1 is a system configuration diagram illustrating an example of a substrate processing system 50 according to one or more embodiments of the present disclosure. The substrate processing system 50 includes a vacuum transfer module (VTM) 51, an accommodation apparatus 52, a plurality of load lock modules (LLMs) 53, an equipment front end module (EFEM) 54, a plurality of process modules (PMs) 1, and a controller 2. The plurality of PMs 1 are connected to a side wall of the VTM 51 via gate valves G1. Note that, in the example of FIG. 1, six PMs 1 are connected to the VTM 51. On the other hand, the number of PMs 1 connected to the VTM 51 may be more than six or may be less than six. The VTM 51 is an example of a vacuum transfer apparatus. The accommodation apparatus 52 is an example of a ring stocker. The PM 1 is an example of a plasma processing apparatus. That is, the substrate processing system 50 includes a VTM 51, a plurality of PMs 1 connected to the VTM 51, an accommodation apparatus 52 connected to the VTM 51, and a controller 2.

Each PM 1 performs processing such as etching or film formation using plasma on a substrate W to be processed. The plurality of LLMs 53 are connected to another side wall of the VTM 51 via gate valves G2. In the example of FIG. 1, two LLMs 53 are connected to the VTM 51. On the other hand, the number of LLMs 53 connected to the VTM 51 may be more than two or may be one.

A transfer robot 510 is disposed in the VTM 51. The transfer robot 510 is an example of a transfer apparatus. The transfer robot 510 includes an arm 511 and a fork 512. The fork 512 is provided at a tip of the arm 511. A substrate W, an edge ring, and a dummy substrate are placed on the fork 512. The dummy substrate is an example of a cleaning substrate. The transfer robot 510 transfers the substrate W between the PM 1 and another PM 1, and between the PM 1 and the LLM 53. Further, the transfer robot 510 transfers the edge ring and the dummy substrate between the PM 1 and the accommodation apparatus 52. The VTM 51 is maintained in a predetermined pressure atmosphere lower than the atmospheric pressure.

The VTM 51 is connected to one side wall of each LLM 53 via a gate valve G2, and the EFEM 54 is connected to the other side wall of each LLM 53 via a gate valve G3. In a case where the substrate W is loaded from the EFEM 54 into the LLM 53 via the gate valve G3, the gate valve G3 is closed, and the pressure in the LLM 53 is decreased to a pressure substantially the same as the pressure in the VTM 51. In addition, the gate valve G2 is opened, and the substrate W in the LLM 53 is unloaded into the VTM 51 by the transfer robot 510.

Further, in a state where the pressure in the LLM 53 is substantially the same as the pressure in the VTM 51, the substrate W is loaded from the VTM 51 into the LLM 53 via the gate valve G2 by the transfer robot 510, and the gate valve G2 is closed. In addition, the pressure in the LLM 53 is increased to a pressure substantially the same as the pressure in the EFEM 54. In addition, the gate valve G3 is opened, and the substrate W in the LLM 53 is unloaded into the EFEM 54.

A plurality of load ports 55 are provided on a side wall of the EFEM 54 opposite to a side wall of the EFEM 54 on which the gate valve G3 is provided. A container such as a front opening unified pod (FOUP) capable of accommodating the plurality of substrates W is connected to each load port 55. Note that the EFEM 54 may include an aligner module or the like that changes an orientation of the substrate W.

The inside of the EFEM 54 is, for example, in the atmospheric pressure. A transfer robot 540 is provided in the EFEM 54. The transfer robot 540 moves in the EFEM 54 along a guide rail 541 provided in the EFEM 54, and transfers the substrate W between the LLM 53 and a container connected to the load port 55. A fan filter unit (FFU) or the like is provided on an upper portion of the EFEM 54, and dry air from which particles or the like are removed is supplied from the upper portion into the EFEM 54. Thus, a down flow is formed in the EFEM 54. Note that, in the present embodiment, the inside of the EFEM 54 is in the atmospheric pressure. As another form, the pressure in the EFEM 54 may be controlled to be a positive pressure. Thereby, it is possible to prevent particles or the like from being intruded from the outside into the EFEM 54.

The accommodation apparatus 52 is connected to another side wall of the VTM 51 via a gate valve G4. The accommodation apparatus 52 accommodates an edge ring and a dummy substrate. In the present embodiment, the accommodation apparatus 52 accommodates an edge ring for replacement, a used edge ring, and a dummy substrate. The accommodation apparatus 52 has a function of switching the pressure in the accommodation apparatus 52 between the atmospheric pressure and a pressure substantially the same as the pressure in the VTM 51. Note that the edge ring for replacement may be a new edge ring or may be a used edge ring with a small amount of consumption.

For example, in a state where the inside of the accommodation apparatus 52 is in a pressure substantially the same as the pressure in the VTM 51, the gate valve G4 is opened, and the used edge ring is accommodated in the accommodation apparatus 52 from the PM 1 via the VTM 51 by the transfer robot 510. In addition, the edge ring for replacement is loaded from the accommodation apparatus 52 into the PM 1 via the VTM 51 by the transfer robot 510. In addition, the gate valve G4 is closed, and the inside of the accommodation apparatus 52 is switched from the pressure substantially the same as the pressure in the VTM 51 to the atmospheric pressure. Thereafter, a gate valve G5 is opened, and the used edge ring is unloaded to the outside of the accommodation apparatus 52 via the gate valve G5. In addition, the edge ring for replacement is loaded into the accommodation apparatus 52 via the gate valve G5.

Further, in a state where the inside of the accommodation apparatus 52 is in a pressure substantially the same as the pressure in the VTM 51, for example, the gate valve G4 is opened, and the dummy substrate is loaded into the PM 1 via the VTM 51 by the transfer robot 510. In addition, after cleaning of the inside of the PM 1 is ended, the dummy substrate is returned again into the accommodation apparatus 52 by the transfer robot 510. In a case where the dummy substrate is replaced, for example, after the inside of the accommodation apparatus 52 is switched from the pressure substantially the same as the pressure in the VTM 51 to the atmospheric pressure, the gate valve G5 is opened, and the dummy substrate is unloaded to the outside of the accommodation apparatus 52 via the gate valve G5. In addition, the dummy substrate for replacement is loaded into the accommodation apparatus 52 via the gate valve G5. The dummy substrate for replacement may be a new dummy substrate, or may be a used dummy substrate with a small amount of consumption.

The controller 2 processes computer-executable instructions for instructing the substrate processing system 50 to execute various processes described in the present disclosure. The controller 2 may be configured to control each element of the substrate processing system 50 to execute various processes described herein. In the embodiment, a part or all of the controller 2 may be included in the substrate processing system 50. The controller 2 may include a processor 2a1, a storage 2a2, and a communication interface 2a3. The controller 2 is implemented by, for example, a computer 2a. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality.” The processor 2a1 may be configured to read a program from the storage 2a2 and perform various control operations by executing the read program. The program may be stored in advance in the storage 2a2, or may be acquired via a medium when necessary. The acquired program is stored in the storage 2a2, and is read from the storage 2a2 and executed by the processor 2a1. The medium may be various storing media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may perform communication with the substrate processing system 50 via a communication line such as a local area network (LAN).

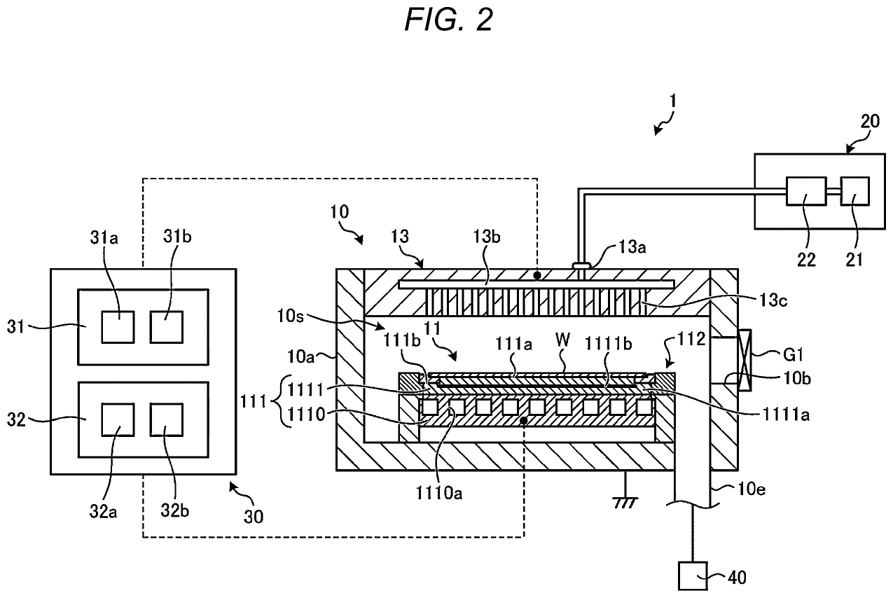

FIG. 2 is a schematic cross-sectional view illustrating an example of a structure of the PM 1 according to the embodiment of the present disclosure. The PM 1 is an example of a substrate processing apparatus.

In the present embodiment, PM 1 is a capacitively-coupled plasma processing apparatus. The PM 1 includes a plasma processing chamber 10, a gas supply 20, a power source 30, and an exhaust system 40. Further, the PM 1 includes a substrate support 11 and a gas introduction unit. The plasma processing chamber 10 is an example of a processing container. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas into the plasma processing space 10s, and at least one gas exhaust port for exhausting the gas from the plasma processing space. The plasma processing chamber 10 is grounded. The shower head 13 and the substrate support 11 are electrically insulated from a housing of the plasma processing chamber 10. An opening 10b for loading the substrate W into the plasma processing chamber 10 and unloading the substrate W from the plasma processing chamber 10 is formed on the side wall 10a of the plasma processing chamber 10. The opening 10b is opened and closed by the gate valve G1.

The substrate support 11 includes a main body 111 and a ring assembly 112. The main body 111 is an example of a stage. The main body 111 has a central region 111a for supporting the substrate W and an annular region 111b for supporting the ring assembly 112. The central region 111a is an example of a first mounting surface, and the annular region 111b is an example of a second mounting surface. A wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and a first electrode 1111b disposed in the ceramic member 1111a. The ceramic member 1111a has the central region 111a. In one embodiment, the ceramic member 1111a also has the annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power source 31 to be described later and/or a direct current (DC) power source 32 to be described later may be disposed in the ceramic member 1111a. In this case, at least one RF/DC electrode functions as the lower electrode. In a case where the bias RF signal and/or the DC signal to be described later are supplied to at least one RF/DC electrode, the RF/DC electrode is also referred to as a bias electrode. The conductive member of the base 1110 and at least one RF/DC electrode may function as a plurality of lower electrodes. Further, the first electrode 1111b may function as a lower electrode. Accordingly, the substrate support 11 includes at least one lower electrode.

The ring assembly 112 includes one or more annular members. In one embodiment, one or more annular members include one or more edge rings and at least one cover ring. The edge ring is formed of a conductive material or an insulating material, and the cover ring is formed of an insulating material.

Further, the substrate support 11 may include a temperature control module configured to adjust at least one of the electrostatic chuck 1111, the ring assembly 112, and the substrate to a target temperature. The temperature control module (i.e., temperature controller) may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between a rear surface of the substrate W and the central region 111a. Further, although not illustrated in FIG. 2, the substrate support 11 includes a plurality of lifter pins.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. Note that the gas introduction unit may include, in addition to the shower head 13, one or a plurality of side gas injectors (SGI) that are attached to one or a plurality of openings formed on the side wall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of at least one processing gas.

The power source 30 includes an RF power source 31 coupled to plasma processing chamber 10 via at least one impedance matching circuit. The RF power source 31 is configured to supply at least one RF signal (RF power) to at least one lower electrode and/or at least one upper electrode. As a result, plasma is formed from at least one processing gas supplied into the plasma processing space 10s. Accordingly, the RF power source 31 may function as at least a portion of a plasma generator configured to generate plasma from one or more processing gases in the plasma processing chamber 10. Further, supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate a bias RF signal (bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is configured to be connected to at least one lower electrode to generate a first DC signal. The generated first bias DC signal is applied to at least one lower electrode. In one embodiment, the second DC generator 32b is configured to be connected to at least one upper electrode to generate a second DC signal. The generated second DC signal is applied to at least one upper electrode.

In various embodiments, at least one of the first and second DC signals may be pulsed. In this case, the sequence of voltage pulses is applied to at least one lower electrode and/or at least one upper electrode. The voltage pulse may have a pulse waveform of a rectangle, a trapezoid, a triangle or a combination thereof. In one embodiment, a waveform generator for generating a sequence of voltage pulses from the DC signal is connected between the first DC generator 32a and at least one lower electrode. Accordingly, the first DC generator 32a and the waveform generator configure a voltage pulse generator. In a case where the second DC generator 32b and the waveform generator configure the voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

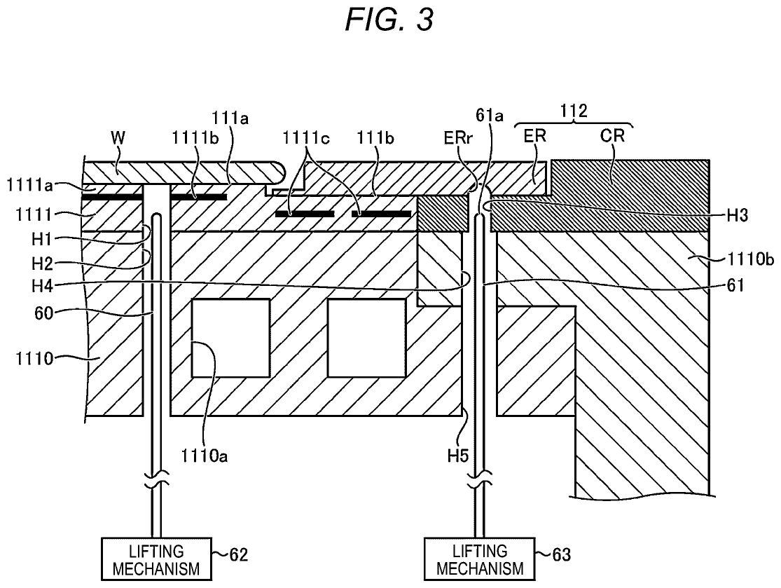

FIG. 3 is an enlarged cross-sectional view illustrating an example of a structure near the edge of the electrostatic chuck 1111. The base 1110 is supported by an insulating member 1110b formed in an annular shape. In the embodiment, the insulating member 1110b is included in the main body 111. That is, the main body 111 serving as a stage includes the base 1110, the electrostatic chuck 1111, and the insulating member 1110b. The ring assembly 112 includes an edge ring ER and a cover ring CR. A part of the edge ring ER is disposed on the annular region 111b. Further, an outer peripheral portion of the edge ring ER and an inner peripheral portion of the cover ring CR overlap with each other in a top view. The edge ring ER is formed of, for example, a conductive material such as silicon or silicon carbide. The cover ring CR is disposed on the insulating member 1110b. The cover ring CR is formed of, for example, an insulating material such as quartz, and protects an upper surface of the insulating member 1110b from plasma. The upper surface of the insulating member 1110b is an example of a third mounting surface. Note that the edge ring ER may be made of, for example, an insulating material such as quartz. Further, the cover ring CR may be made of, for example, a conductive material such as silicon or silicon carbide.

In the electrostatic chuck 1111, the first electrode 1111b is embedded below the central region 111a, and a second electrode 1111c is embedded below the annular region 111b. The first electrode 1111b attracts the substrate W or the dummy substrate onto the central region 111a by an electrostatic force generated based on the applied voltage. The second electrode 1111c attracts the edge ring ER onto the annular region 111b by an electrostatic force generated based on the applied voltage. In the example of FIG. 3, the first electrode 1111b is a unipolar electrode. On the other hand, as another example, the first electrode 1111b may be a bipolar electrode. Further, in the example of FIG. 3, the second electrode 1111c is a bipolar electrode. On the other hand, as another example, the second electrode 1111c may be a unipolar electrode.

Below the central region 111a, the electrostatic chuck 1111 has a through-hole H1 formed therein, and the base 1110 has a through-hole H2 formed therein. A lifter pin 60 is inserted into the through-hole H1 and the through-hole H2. The lifter pin 60 is lifted and lowered by a lifting mechanism 62. The lifter pin 60 is lifted and lowered, and thus, the substrate W or the dummy substrate placed on the central region 111a can be lifted and lowered. In the present embodiment, three lifter pins 60 are provided in the central region 111a.

Below a region where the edge ring ER and the cover ring CR overlap with each other in a top view, a through-hole H3 is formed in the cover ring CR, a through-hole H4 is formed in the insulating member 1110b, and a through-hole H5 is formed in the base 1110. A lifter pin 61 is inserted into the through-holes H3 to H5. The lifter pin 61 is lifted and lowered by a lifting mechanism 63. The lifter pin 61 is lifted and lowered, and thus, the edge ring ER on the cover ring CR can be lifted and lowered. In the present embodiment, three lifter pins 61 are provided in the annular region 111b. Note that a recess ERr is formed on a lower surface of the edge ring ER corresponding to a position of the through-hole H3. In a case where the lifter pin 61 is lifted, a tip 61a of the lifter pin 61 comes into contact with the recess ERr. Thereby, the lifter pins 61 can stably support the edge ring ER by the tips 61a. The lifting mechanism 63 is an example of a lifter.

### Substrate Processing Method

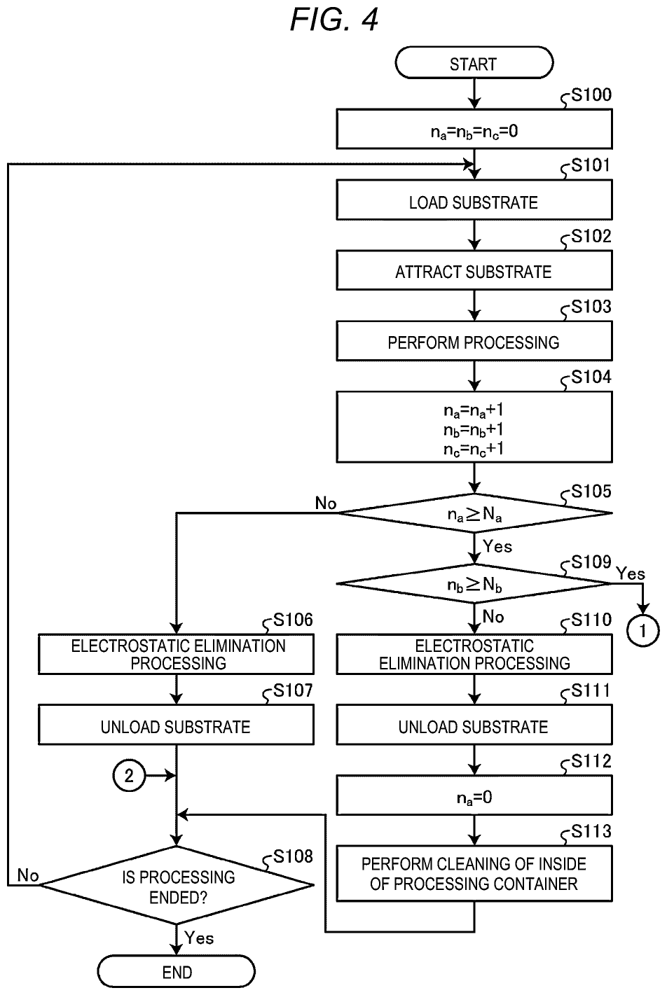

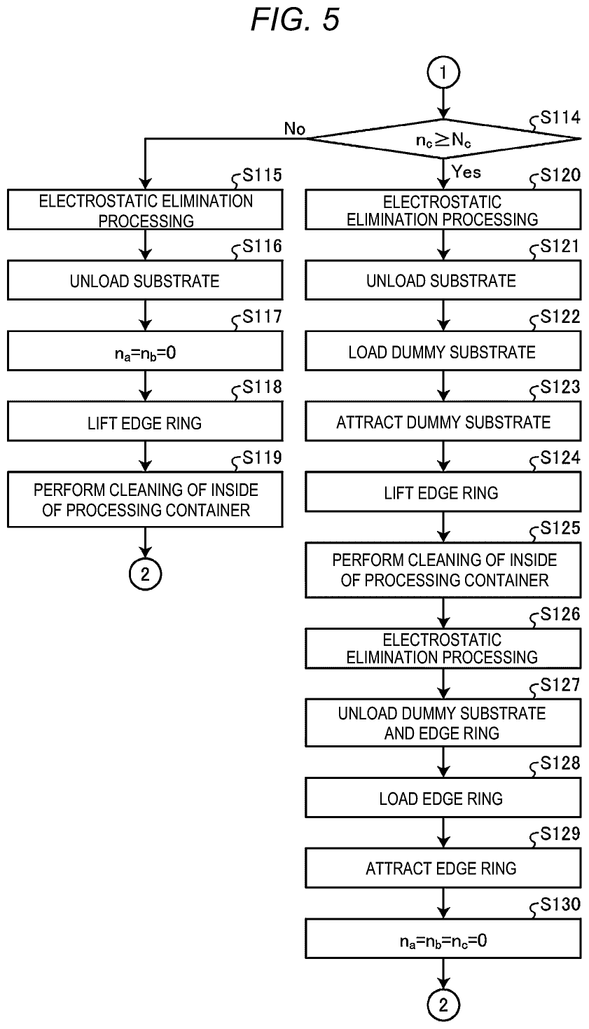

FIG. 4 and FIG. 5 are flowcharts illustrating an example of a substrate processing method. Each step illustrated in FIG. 4 and FIG. 5 is implemented when the controller 2 controls each unit of the substrate processing system 50. The substrate processing method illustrated in FIG. 4 and FIG. 5 is an example of a cleaning method.

First, the values of variables nₐ, n_{b}, and n_{c} are initialized to 0 (S100). The variable nₐ is a variable for counting the number of times that the substrate W is processed before cleaning is performed without the edge ring ER being lifted. The variable n_{b} is a variable for counting the number of times that the substrate W is processed before cleaning is performed with the edge ring ER being lifted. The variable n_{c} is a variable for counting the number of times that the substrate W is processed before the edge ring ER is replaced.

Next, the substrate W is loaded into the PM 1 (S101). In step S101, the gate valve G1 is opened, and the substrate W is loaded into the PM 1 by the transfer robot 510. Then, the lifter pins 60 are lifted from the central region 111a of the electrostatic chuck 1111, and thus the substrate W is transferred to the lifter pins 60. The lifter pins 60 are then lowered by driving of the lifting mechanism 62, and thus the substrate W is placed on the central region 111a of the electrostatic chuck 1111.

Next, the substrate W is attracted onto the central region 111a (S102). In step S102, the substrate W is attracted and held onto the central region 111a by an electrostatic force generated based on the voltage applied to the first electrode 1111b. Processing such as plasma etching is then performed on the substrate W (S103). Step S103 is an example of a process a).

When the processing on the substrate W is ended, the variables nₐ, n_{b}, and n_{c} are each incremented by 1 (S104). In addition, it is determined whether the value of the variable nₐ is equal to or larger than the value of Nₐ that is predetermined (S105). The value of Nₐ is, for example, 10. The value of Nₐ is an example of a second number.

When the value of the variable nₐ is smaller than the value of Nₐ (No in S105), electrostatic elimination processing of the substrate W is performed (S106). In step S106, for example, a predetermined gas (e.g., a nitrogen gas) at a predetermined flow rate is supplied into the plasma processing chamber 10, and the inside of the plasma processing chamber 10 is controlled to a predetermined pressure. A voltage having a polarity different from the polarity of the voltage applied to the first electrode 1111b is then applied to the first electrode 1111b for a predetermined time, and thereafter, the application of the voltage to the first electrode 1111b is stopped. Thus, charges accumulated on the substrate W can be discharged via the gas in the plasma processing chamber 10. Note that the electrostatic elimination processing is not limited to the above method and other methods may be used. For example, a predetermined gas (e.g., a nitrogen gas) at a predetermined flow rate is supplied into the plasma processing chamber 10, and the inside of the plasma processing chamber 10 is controlled to a predetermined pressure. Then, RF power for plasma generation is supplied to the lower electrode or the upper electrode to generate plasma. A voltage having a polarity different from the polarity of the voltage applied to the first electrode 1111b is then applied for a predetermined time. Thereafter, the application of the voltage to the first electrode 1111b is stopped, and the supply of the RF power for plasma generation is also stopped. Thus, this causes charges accumulated on the substrate W to be discharged via the plasma in the plasma processing chamber 10.

Next, the processed substrate W is unloaded (S107). In step S107, the lifter pins 60 are lifted by driving of the lifting mechanism 62 to lift the substrate W. The gate valve G1 is then opened, and the substrate W is unloaded from the PM 1 by the transfer robot 510.

Next, it is determined whether the processing of the substrate W is to be ended (S108). When the processing of the substrate W is not to be ended (No in step S108), processing of step S101 is performed again. When the processing of the substrate W is to be ended (Yes in S108), the substrate processing method illustrated in the flowchart is ended.

On the other hand, when the value of the variable nₐ is equal to or larger than the value of Nₐ (Yes in S105), it is determined whether the value of the variable n_{b} is equal to or larger than a value of N_{b} that is predetermined (S109). The value of N_{b} is, for example, 100. The value of N_{b} is an example of a first number.

When the value of the variable n_{b} is smaller than the value of N_{b} (No in S109), electrostatic elimination processing of the substrate W is performed (S110). In step S110, electrostatic elimination processing of the substrate W is performed with the same procedure as in step S106. The processed substrate W is then unloaded (S111). The value of the variable nₐ is then initialized to 0 (S112).

Next, the inside of the plasma processing chamber 10 is cleaned (step S113). Step S113 is an example of a process e), and the cleaning performed in step S113 is an example of third cleaning. In step S113, with the edge ring ER placed on the annular region 111b, the inside of the plasma processing chamber 10 is cleaned. In step S113, a cleaning gas is supplied into the plasma processing chamber 10, and the inside of the plasma processing chamber 10 is cleaned with plasma generated from the cleaning gas. The processing of step S108 is then performed.

The cleaning gas supplied into the plasma processing chamber 10 in step S113 includes, for example, at least one gas selected from the group consisting of an O₂ gas, a CO gas, a CO₂ gas, a COS gas, an N₂ gas, and an H₂ gas. Note that the cleaning gas may further include a halogen-containing gas such as a CF₄ gas, an NF₃ gas, a Cl₂ gas, or an HBr gas.

On the other hand, when the value of the variable n_{b} is equal to or larger than the value of N_{b} (Yes in S109), it is determined whether the value of the variable n_{c} is equal to or larger than a value of N_{c} that is predetermined (S114). The value of N_{c} is, for example, 1000.

When the value of the variable n_{c} is smaller than the value of N_{c} (No in S114), electrostatic elimination processing of the substrate W and the edge ring ER is performed (S115). In step S115, the application of the voltages to the first electrode 1111b and the second electrode 1111c is stopped, and, for example, a predetermined gas (e.g., a nitrogen gas) at a predetermined flow rate is supplied into the plasma processing chamber 10. Thus, the inside of the plasma processing chamber 10 is controlled to a predetermined pressure. A voltage having a polarity different from the polarity of the voltage applied to the first electrode 1111b is then applied to the first electrode 1111b for a predetermined time, and a voltage having a polarity different from the polarity of the voltage applied to the second electrode 1111c is applied to the second electrode 1111c for a predetermined time. The application of the voltages to the first electrode 1111b and the second electrode 1111c is then stopped. Thereby, charges accumulated on the substrate W and the edge ring ER can be discharged via the gas in the plasma processing chamber 10. In the present embodiment, in step S115, electrostatic elimination processing of the substrate W and electrostatic elimination processing of the edge ring ER are performed at the same time. In this case, the processing time can be shorter than when electrostatic elimination processing of the substrate W and electrostatic elimination processing of the edge ring ER are performed at different timings. Note that, after electrostatic elimination processing of the substrate W is performed and the substrate W is unloaded, electrostatic elimination processing of the edge ring ER may be performed.

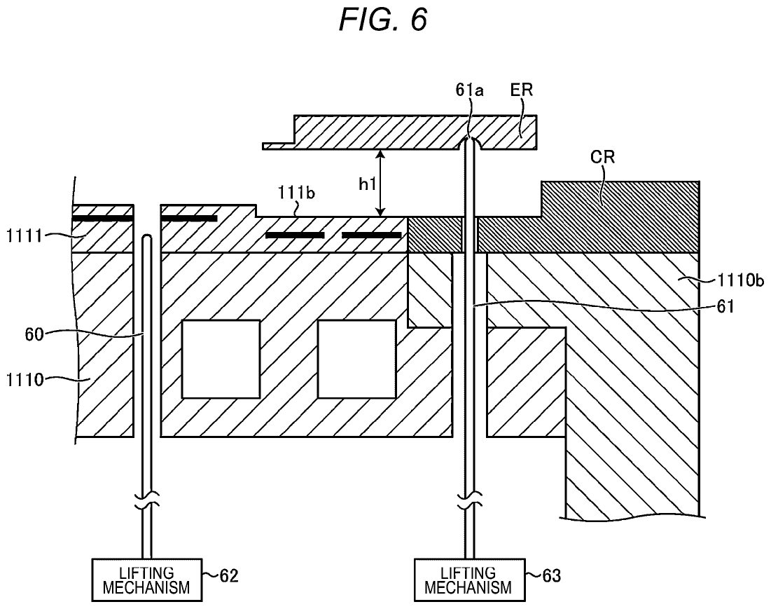

Next, the processed substrate W is unloaded (S116), and the values of the variables nₐ and n_{b} are initialized to 0 (S117). The edge ring ER is then lifted (S118). In step S118, for example, as illustrated in FIG. 6, the lifter pins 61 are lifted by driving of the lifting mechanism 63, and thus the edge ring ER is lifted. As a result, the edge ring ER is separated from the annular region 111b. In step S118, a height from the annular region 111b to the lower surface of the edge ring ER is defined as h1.

Next, the inside of the plasma processing chamber 10 is cleaned (S119). In step S119, with the edge ring ER separated from the annular region 111b, the inside of the plasma processing chamber 10 is cleaned. In step S119, a cleaning gas is supplied into the plasma processing chamber 10, and the inside of the plasma processing chamber 10 is cleaned with plasma generated from the cleaning gas. This can efficiently remove the deposits attached to the lower surface of the edge ring ER, the inner peripheral portion of the edge ring ER, the annular region 111b, and the outer peripheral portion (the side wall between the central region 111a and the annular region 111b) of the central region 111a. The processing of step S108 is then performed.

The cleaning gas supplied into the plasma processing chamber 10 in step S119 may be the same as or different from the cleaning gas supplied into the plasma processing chamber 10 in step S113. Step S119 is an example of a process b), and the cleaning performed in step S119 is an example of first cleaning. A processing condition for the cleaning in step S119 includes parameters including the type of gas, the ratio of gas flow rates, a gas flow rate, a pressure, bias power, plasma generation power, and the temperature of the stage.

In this manner, in the present embodiment, the inside of the plasma processing chamber 10 is cleaned with the edge ring ER lifted not only immediately before the edge ring ER is replaced, but also each time a predetermined number of substrates W are processed. This can remove the deposits attached to the edge ring ER before such deposits that cannot be completely removed by cleaning are attached to the edge ring ER. This can more efficiently remove the deposits attached to the edge ring ER.

When the value of the variable n_{c} is equal to or larger than the value of N_{c} (Yes in S114), electrostatic elimination processing of the substrate W and the edge ring ER is performed (S120). In step S120, electrostatic elimination processing of the substrate W and the edge ring ER is performed in the same procedure as in step S115. The processed substrate W is then unloaded (S121).

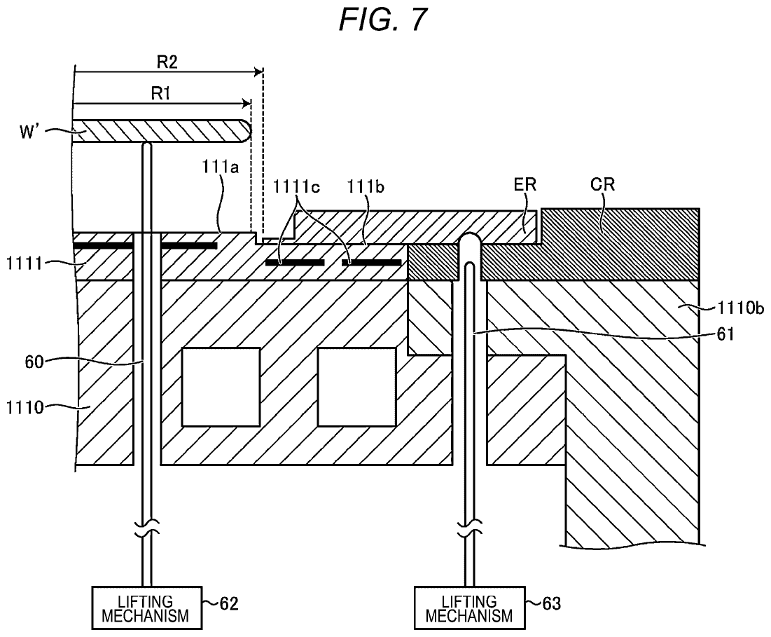

Next, the dummy substrate is loaded into the plasma processing chamber 10 (S122). In step S122, the gate valve G4 is opened, and the dummy substrate is unloaded from the accommodation apparatus 52 by the transfer robot 510. The gate valve G1 is then opened, and the dummy substrate W′ is loaded into the PM 1. As illustrated in FIG. 7, for example, the dummy substrate W′ is transferred to the lifter pins 60. The lifter pins 60 are then lowered by driving of the lifting mechanism 62, and thus the dummy substrate W′ is placed on the central region 111a of the electrostatic chuck 1111.

Here, for example, as illustrated in FIG. 7, a diameter R1 of the dummy substrate W′is shorter than an inner diameter R2 of the edge ring ER. Therefore, even when the dummy substrate W′ is on the central region 111a, the edge ring ER can be lifted without interference with the dummy substrate W′.

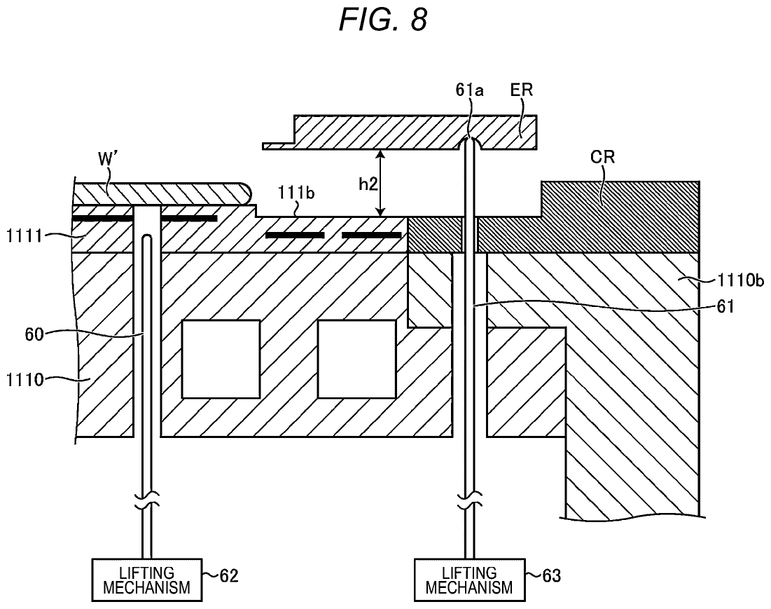

Next, the dummy substrate W′ is attracted onto the central region 111a (S123). The edge ring ER is then lifted (S124). In step S124, the lifter pins 61 are lifted by driving of the lifting mechanism 63, and thus, for example, as illustrated in FIG. 8, the edge ring ER is lifted. Thus, the edge ring ER is separated from the annular region 111b. In the present embodiment, a height h2 from the annular region 111b to the lower surface of the edge ring ER in step S124 is different from the height h1 from the annular region 111b to the lower surface of the edge ring ER in step S118. For example, the height h2 is lower than the height h1. As the height from the annular region 111b to the lower surface of the edge ring ER is lower, the density of plasma between the annular region 111b and the lower surface of the edge ring ER is higher. This improves the cleaning performance around the edge ring ER. Note that, as the density of the plasma is higher, the cleaning performance is improved. On the other hand, damage to the central region 111a of the electrostatic chuck 1111 increases. Therefore, the dummy substrate W′ is placed on the central region 111a, and thus damage to the central region 111a can be reduced. Note that, in another embodiment, the height h2 and the height h1 may be the same height and the height h2 may be higher than the height h1.

Next, the inside of the plasma processing chamber 10 is cleaned (S125). Step S125 is an example of a process c), and the cleaning performed in step S125 is an example of second cleaning. In step S125, with the dummy substrate W′ placed on the central region 111a and the edge ring ER separated from the annular region 111b, the inside of the plasma processing chamber 10 is cleaned. In step S125, a cleaning gas is supplied into the plasma processing chamber 10, and the inside of the plasma processing chamber 10 is cleaned with plasma generated from the cleaning gas. The cleaning gas supplied into the plasma processing chamber 10 in step S125 may be the same as or different from the cleaning gas supplied into the plasma processing chamber 10 in step S113 or S119. A processing condition for the cleaning in step S125 includes parameters including the type of a gas, the ratio of gas flow rates, a gas flow rate, a pressure, bias power, plasma generation power, and the temperature of the stage.

Note that the processing condition for the cleaning in step S125 may be obtained by changing at least one parameter of the processing condition for the cleaning in step S119. The processing condition for the cleaning in step S125 and the processing condition for the cleaning in step S119 include, for example, at least one parameter selected from the parameter group consisting of the type of a gas, the ratio of gas flow rates, a gas flow rate, a pressure, bias power, plasma generation power, the temperature of the electrostatic chuck 1111, and a cleaning time.

Here, in step S125, preferably, the cleaning is performed under a condition where the cleaning performance is higher than the cleaning performance of the cleaning performed in step S119. This can sufficiently remove the deposits attached to the used edge ring ER, and can prevent the deposits from falling during a transfer process of the used edge ring ER. For example, the plasma generation power supplied to the upper electrode and/or the lower electrode in the cleaning in step S125 may be higher than the plasma generation power supplied in the first cleaning. Accordingly, the PM 1 further includes at least one first RF generator 31a. First plasma is generated with first source RF power from the at least one first RF generator 31a, and second plasma is generated with second source RF power from the at least one first RF generator 31a. The second source RF power is higher than the first source RF power. Further, the cleaning in step S125 may be performed with bias power higher than bias power in the cleaning in step S119. Alternatively, the bias power may not be supplied in the cleaning in step S119, and the bias power may be supplied in the cleaning in step S125. Accordingly, the PM 1 includes at least one bias electrode disposed in the substrate support 11, and at least one second RF generator 31b. The at least one second RF generator 31b is configured to supply the first bias RF power to the at least one bias electrode in the first cleaning, and supply the second bias RF power to the at least one bias electrode in the second cleaning. The second bias RF power is higher than the first bias RF power. In the embodiment, the first bias RF power has a zero power level. Further, in the embodiment, the PM 1 may include at least one voltage pulse generator. The at least one voltage pulse generator is configured to supply a sequence of a plurality of first voltage pulses to the at least one bias electrode in the first cleaning, and supply a sequence of a plurality of second voltage pulses to the at least one bias electrode in the second cleaning. The first voltage pulse has a first voltage level, and the second voltage pulse has a second voltage level. The second voltage pulse is higher than the first voltage level. In one embodiment, the first voltage level has a zero voltage level. Further, the cleaning in step S125 may be performed at a higher pressure than the cleaning in step S119. Therefore, in the embodiment, the first cleaning is performed at a first pressure, and the second cleaning is performed at a second pressure higher than the first pressure. Further, the cleaning in step S125 may be performed at a higher pressure and with higher bias power than in the cleaning in step S119. Further, the temperature of the electrostatic chuck 1111 during the cleaning in step S125 may be higher than the temperature of the electrostatic chuck 1111 during the cleaning in step S119. Accordingly, in the embodiment, the PM 1 further includes a temperature control module. The temperature control module is configured to maintain the substrate support 11 at a first temperature during the first cleaning, and maintain the substrate support 11 at a second temperature higher than the first temperature during the second cleaning. Further, the cleaning in step S125 may be performed for a longer time than the cleaning in step S119. Further, in step S125, the cleaning may be performed using a gas (e.g., a halogen-containing gas) that has a higher corrosivity than the gas used in the cleaning performed in step S119. Further, a gas having a high corrosivity (e.g., a halogen-containing gas) may also be used in the cleaning in step S119, and the flow rate of the gas having a high corrosivity in the cleaning in step S125 may be higher than the flow rate of the gas having a high corrosivity in the cleaning in step S119. Further, in step S125, with the dummy substrate W′ placed on the central region 111a, the cleaning is performed. Thereby, even when cleaning of the inside of the plasma processing chamber 10 is performed under a condition where the cleaning performance is high, damage to the central region 111a can be reduced. Note that, in another embodiment, the cleaning performed in step S125 may be performed without the dummy substrate W′ placed on the central region 111a.

Next, electrostatic elimination processing of the dummy substrate W′ is performed (S126). In step S126, electrostatic elimination processing of the substrate W is performed in the same procedure as in step 106. The dummy substrate W′ and the edge ring ER are then unloaded (S127). In step S127, the lifter pins 60 are lifted by driving of the lifting mechanism 62, and thus the dummy substrate W′ is lifted. The gate valve G1 is then opened, and the dummy substrate W′ is unloaded from the PM 1 and is returned into the accommodation apparatus 52 by the transfer robot 510. Further, the edge ring ER is unloaded from the PM 1 and is loaded into the accommodation apparatus 52 by the transfer robot 510. The step S127 is an example of a process d).

Next, the edge ring ER for replacement is loaded into the PM 1 (S128). In step S128, the edge ring ER for replacement is unloaded from the accommodation apparatus 52 by the transfer robot 510, and the edge ring ER for replacement is loaded into the PM 1 by the transfer robot 510. Note that, in step S128, the edge ring ER that is used but has a small amount of consumption may be loaded into the PM 1.

Next, the edge ring ER for replacement is attracted onto the annular region 111b (S129). In step S129, the edge ring ER is attracted and held onto the annular region 111b by an electrostatic force generated based on the voltage applied to the second electrode 1111c. The values of the variables nₐ, n_{b}, and n_{c} are then initialized to 0 (S130), and the processing of step S108 is performed. Note that, after step S129, processing of adjusting the condition of the inside of the plasma processing chamber 10, such as seasoning, may be performed.

One or more embodiments have been described above. As described above, the substrate processing apparatus (PM 1) according to the present embodiment includes the processing container (the plasma processing chamber 10), the stage (the main body 111), the edge ring ER, the lifter (the lifting mechanism 63), and the controller 2. The stage is provided in the processing container, and has the first mounting surface (the central region 111a) on which the substrate W is to be placed and the second mounting surface (111b) that surrounds an outer periphery of the first mounting surface. The edge ring ER is configured to be placed on the second mounting surface. The lifter lifts and lowers the edge ring ER with respect to the second mounting surface. The controller 2 is configured to perform the process a), the process b), and the process c). In the process a), the controller 2 performs plasma processing on the substrate W placed on the first mounting surface. Further, in the process b), each time the process a) is performed on the predetermined first number (N_{b}) of the substrates W, the controller 2 controls the lifter to separate the edge ring ER from the second mounting surface, and performs the first cleaning of the inside of the processing container. Further, in the process c), before replacing the edge ring ER, the controller 2 controls the lifter to separate the edge ring ER from the second mounting surface, and performs the second cleaning of the inside of the processing container. That is, the controller 2 is configured to control each element of the substrate processing system 50 to perform the following processes.
a) A process of performing plasma processing on the substrate W on the substrate mounting surface by controlling each element of the PM 1
b) A process of performing the process a) on the first number of the substrates W
c) A process of, after the process b), lifting the edge ring ER with respect to the ring mounting surface with the plurality of lifter pins 61 by controlling at least one lifting mechanism 63
d) A process of, in a state of the process c), performing first cleaning in the plasma processing chamber 10 with first plasma generated from the first cleaning gas by controlling each element of the PM 1
e) A process of performing the process a) on the second number of the substrates W, the second number being larger than the first number
f) A process of, after the process e), lifting the edge ring ER with respect to the ring mounting surface with the plurality of lifter pins 61 by controlling each element of the substrate processing system 50
g) A process of, in a state of the process f), performing second cleaning in the plasma processing chamber 10 with second plasma generated from the second cleaning gas by controlling each element of the PM 1

This can more efficiently remove the deposits attached to the edge ring ER.

Further, in the embodiment described above, the processing condition in the second cleaning may be obtained by changing at least one parameter of the processing condition in the first cleaning. The processing condition in the first cleaning and the processing condition in the second cleaning may include at least one parameter selected from the parameter group consisting of the type of a gas, the ratio of gas flow rates, a gas flow rate, a pressure, bias power, plasma generation power, the temperature of the stage, and a cleaning time. For example, the second cleaning may be performed with plasma generation power higher than plasma generation power in the first cleaning. Alternatively, the bias power may not be supplied in the first cleaning, and the bias power may be supplied in the second cleaning. Further, the second cleaning may be performed at a pressure higher than a pressure in the first cleaning. Further, the second cleaning may be performed with bias power higher than bias power in the first cleaning. Further, the temperature of the stage in the second cleaning may be higher than the temperature of the stage in the first cleaning. Further, the cleaning time in the second cleaning may be longer than the cleaning time in the first cleaning. This can efficiently remove the deposits attached to the lower surface of the edge ring ER, the inner peripheral portion of the edge ring ER, the annular region 111b, and the outer peripheral portion (the side wall between the central region 111a and the annular region 111b) of the central region 111a. Therefore, when the edge ring ER is replaced, this can reduce generation of particles due to deposits from the used edge ring ER.

Further, in the embodiment described above, the second cleaning is performed in a state where the dummy substrate W′ is placed on the first mounting surface. This can reduce damage to the central region 111a caused by the cleaning.

Further, in the embodiment described above, the height h1 from the second mounting surface to the edge ring ER when the first cleaning is performed may be different from the height h2 from the second mounting surface to the edge ring ER when the second cleaning is performed. For example, the height h2 may be lower than the height h1. Thereby, the density of the plasma around the edge ring ER can be increased, and the cleaning performance in the second cleaning can be improved.

Further, in the embodiment described above, the controller 2 is configured to further perform the process e). In the process e), with the edge ring ER placed on the second mounting surface, the third cleaning of the inside of the processing container is performed. Further, the process e) is performed each time the process a) is performed on the second number (Nₐ) of the substrates W, where the second number is smaller than the first number. This can reduce the deposits in the processing container.

Further, in the embodiment described above, the first electrode 1111b is embedded in the inside of the stage corresponding to the first mounting surface, and the second electrode 1111c is embedded in the inside of the stage corresponding to the second mounting surface. The substrate W is attracted onto the first mounting surface by an electrostatic force generated by the voltage applied to the first electrode 1111b. The edge ring ER is attracted onto the second mounting surface by an electrostatic force generated by the voltage applied to the second electrode 1111c. The controller 2 is configured to perform, before the process b) and the process c) are performed, electrostatic elimination processing on the edge ring ER at the same timing as the timing of the electrostatic elimination processing performed on the substrate W for which processing of the process a) is ended. In this case, the processing time can be shorter than when electrostatic elimination processing of the substrate W and electrostatic elimination processing of the edge ring ER are performed at different timings.

Further, in the embodiment described above, in the first cleaning and the second cleaning, the cleaning of the inside of the processing container is performed using plasma generated from the cleaning gas including at least one gas selected from the group consisting of an O₂ gas, a CO gas, a CO₂ gas, a COS gas, an N₂ gas, and an H₂ gas. This can remove the deposits attached to the edge ring ER.

Further, in the embodiment described above, in the second cleaning, a halogen-containing gas such as a CF₄ gas, an NF₃ gas, a Cl₂ gas, or an HBr gas may be further supplied into the processing container. Further, in the first cleaning, a halogen-containing gas may be further supplied into the processing container, and the flow rate of the halogen-containing gas supplied into the processing container in the second cleaning may be higher than the flow rate of the halogen-containing gas supplied into the processing container in the first cleaning. This can more efficiently remove the deposits attached to the edge ring ER.

Further, the substrate processing system 50 according to the present embodiment includes the vacuum transfer apparatus (VTM 51) configured to transfer the substrate W in a vacuum environment, the substrate processing apparatus (PM 1) configured to process the substrate W, and the accommodation apparatus 52 configured to accommodate the dummy substrate W′. The substrate processing apparatus includes the processing container, the stage, the edge ring ER, the lifting mechanism 63, and the controller 2. The stage is provided in the processing container, and has the first mounting surface on which the substrate W is to be placed and a second mounting surface that surrounds an outer periphery of the first mounting surface. The edge ring ER is formed in an annular shape, and is configured to be placed on the second mounting surface. The lifting mechanism 63 lifts and lowers the edge ring ER with respect to the second mounting surface. The controller 2 is configured to perform the process a), the process b), and the process c). In the process a), the controller 2 performs plasma processing on the substrate W placed on the first mounting surface. Further, in the process b), each time the process a) is performed on the predetermined first number of the substrates W, the controller 2 performs the first cleaning of the inside of the processing container in a state where the edge ring ER is separated from the second mounting surface by controlling the lifting mechanism 63. Further, in the process c), before the edge ring ER is replaced, the controller 2 performs the second cleaning of the inside of the processing container with the edge ring ER separated from the second mounting surface by controlling the lifting mechanism 63. In the second cleaning, the dummy substrate is transferred from the accommodation apparatus into the processing container, and the second cleaning is performed in a state where the dummy substrate W′ is placed on the first mounting surface. This can more efficiently remove the deposits attached to the edge ring ER.

Further, in the embodiment described above, the accommodation apparatus 52 accommodates the edge ring ER for replacement. This can reduce an accommodation space for the dummy substrate W′ and the edge ring ER.

Further, the cleaning method according to the present embodiment includes the process a), the process b), and the process c). In the process a), plasma processing is performed on the substrate placed on the first mounting surface of the stage provided in the processing container. In the process b), the first cleaning of the inside of the processing container is performed with the edge ring separated from the second mounting surface by the lifting mechanism. The edge ring is placed on the second mounting surface of the stage that surrounds the outer periphery of the first mounting surface and disposed to surround the substrate W placed on the first mounting surface. In the process c), before the edge ring ER is replaced, with the edge ring ER separated from the second mounting surface, the second cleaning of the inside of the processing container is performed. The process b) is performed each time the process a) is performed on the predetermined first number of the substrates W. This can more efficiently remove the deposits attached to the edge ring ER.

### Other

The technology disclosed in the present application is not limited to the above-described embodiment, and various modifications are possible within the scope of the gist thereof.

For example, in the embodiment described above, in step S113 and step S119, the cleaning is performed without placing the dummy substrate W′ on the central region 111a. On the other hand, the disclosed technology is not limited thereto. As another form, even in step S113 and step S119, the cleaning may be performed in a state where the dummy substrate W′ is placed on the central region 111a. Thereby, it is possible to reduce a damage to the central region 111a of the electrostatic chuck 1111 during the cleaning.

Further, in the embodiment described above, in step S127, after the dummy substrate W′ is unloaded, the edge ring ER is unloaded. On the other hand, the disclosed technology is not limited thereto. As another form, in step S127, after the edge ring ER is unloaded, the dummy substrate W′ may be unloaded. Thereby, it is possible to prevent the deposits from falling from the edge ring ER onto the central region 111a when the edge ring ER is unloaded.

Further, in the embodiment described above, after the dummy substrate W′ is unloaded in step S127, the edge ring ER for replacement is loaded in step S128. On the other hand, the disclosed technology is not limited thereto. As another form, after the edge ring ER for replacement is loaded, the dummy substrate W′ may be unloaded. Thereby, it is possible to prevent particles or the like attached to the edge ring ER for replacement from falling onto the central region 111a.

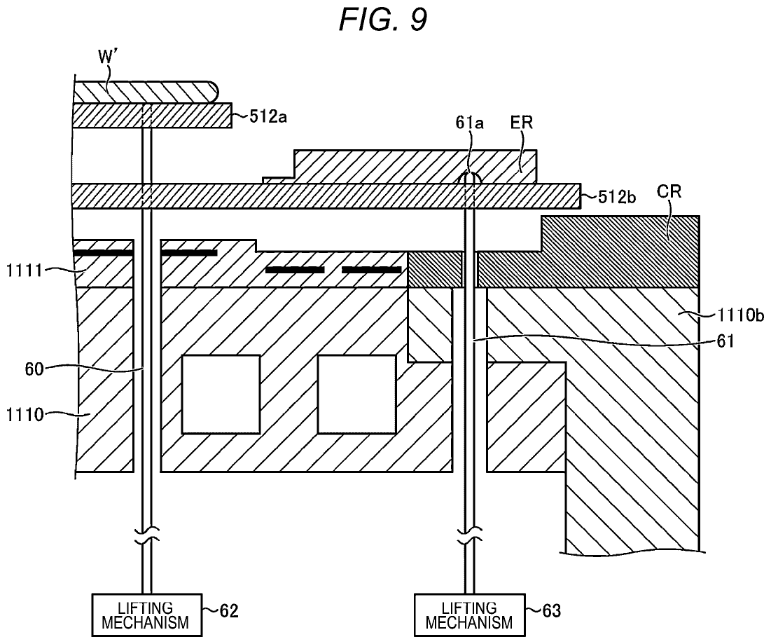

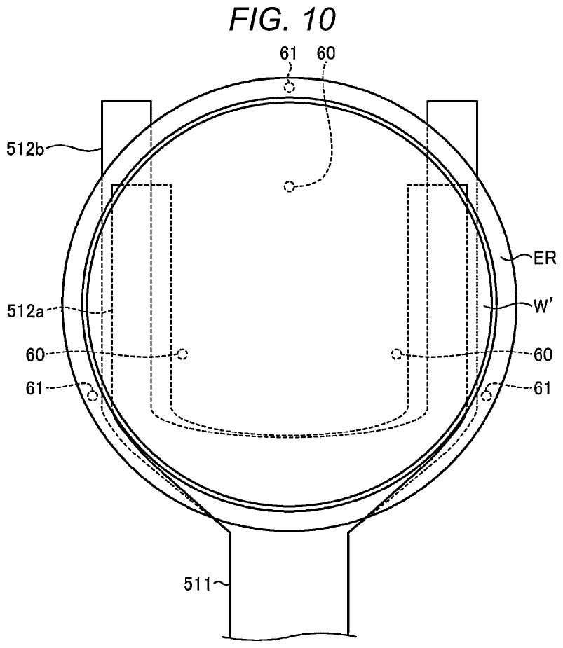

Further, in the embodiment described above, in step S127, after the dummy substrate W′ is unloaded, the used edge ring ER is unloaded. On the other hand, the disclosed technology is not limited thereto. As another form, for example, as illustrated in FIG. 9 and FIG. 10, the dummy substrate W′ and the edge ring ER may be simultaneously unloaded using the transfer robot 510 in which a first fork 512a and a second fork 512b are provided on the arm 511. In the examples of FIG. 9 and FIG. 10, the dummy substrate W′ is supported by the first fork 512a provided above, and the edge ring ER is supported by the second fork 512b provided below. Thereby, it is possible to reduce a time required for unloading the dummy substrate W′ and the edge ring ER. Note that the edge ring ER may be supported by the first fork 512a provided above and the dummy substrate W′ may be supported by the second fork 512b provided below.

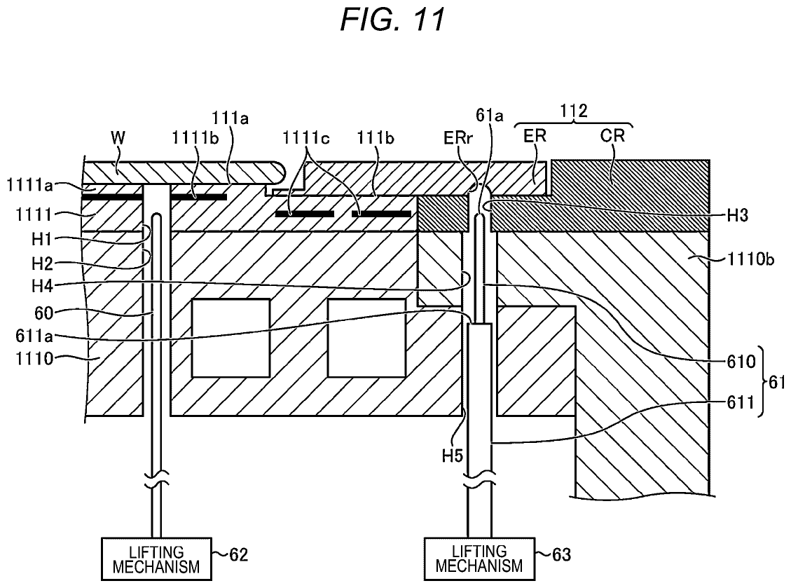

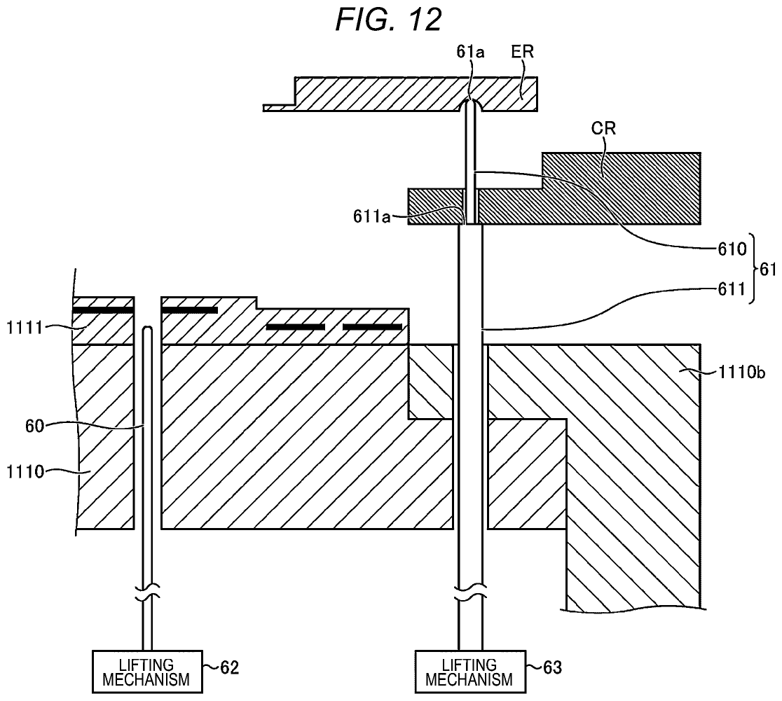

Further, in the embodiment described above, the edge ring ER is replaced by the transfer robot 510. On the other hand, the disclosed technology is not limited thereto. The edge ring ER and the cover ring CR may be replaced by the transfer robot 510. FIG. 11 is an enlarged cross-sectional view illustrating another example of a structure near the edge of the electrostatic chuck 1111. In the example of FIG. 11, the lifter pin 61 includes an upper portion 610 and a lower portion 611 thicker than the upper portion 610. The upper portion 610 is thinner than the inner diameters of the through-holes H3 to H5. On the other hand, the lower portion 611 is thinner than the inner diameters of the through-holes H4 and H5, but thicker than the inner diameter of the through-hole H3. The edge ring ER is an example of a first ring. The cover ring CR is an example of a second ring. The lifting mechanism 63 is an example of at least one actuator. Accordingly, in the examples of FIG. 11 and FIG. 12, the PM 1 includes the plasma processing chamber 10, the substrate support 11, the first ring ER, the second ring CR, the plurality of lifter pins 61, and at least one lifting mechanism 63. The substrate support 11 is disposed in the plasma processing chamber 10, and has a substrate mounting surface, a first ring mounting surface, and a second ring mounting surface. The first ring ER is disposed to surround the substrate W on the substrate mounting surface, and includes an inner annular portion and an outer annular portion. The inner annular portion of the first ring ER is mounted on the first ring mounting surface. The second ring CR includes an inner annular portion and an outer annular portion. The inner annular portion of the second ring CR is configured to support the outer annular portion of the first ring ER, and the outer annular portion of the second ring CR is mounted on the second ring mounting surface. The inner annular portion of the second ring CR has a plurality of through-holes H3. The plurality of lifter pins 61 are respectively aligned with the plurality of through-holes H3. Each of the lifter pins 61 includes an upper portion 610 and a lower portion 611. The upper portion 610 of the lifter pin 61 is configured to support the first ring ER via the corresponding through-hole H3. A dimension of the upper portion 610 of the lifter pin 61 in a horizontal direction is smaller than a dimension of the corresponding through-hole H3 in a horizontal direction. A dimension of the lower portion 611 of the lifter pin 61 in a horizontal direction is larger than a dimension of the corresponding through-hole H3 in a horizontal direction. At least one lifting mechanism 63 moves the plurality of lifter pins 61 in a vertical direction.

The upper portion 610 is longer than h1. Therefore, the lifter pins 61 are lifted, and thus, the lifter pins 61 can lift only the edge ring ER to the height h1. Further, the lifter pins 61 are further lifted, and thus, for example, as illustrated in FIG. 12, the cover ring CR can be further lifted by an upper end surface 611a of the lower portion 611. In step S125, cleaning is performed in a state where the edge ring ER and the cover ring CR are lifted to a state of FIG. 12, and thus, the deposits attached to the lower surface of the cover ring CR and the upper surface of the insulating member 1110b can also be efficiently removed. After cleaning of the edge ring ER and the cover ring CR is performed, the edge ring ER and the cover ring CR are unloaded by the transfer robot 510, and are replaced with the edge ring ER for replacement and the cover ring CR for replacement. Accordingly, the controller 2 is configured to perform the following processes by controlling each element of the substrate processing system 50.
a) A process of performing plasma processing on the substrate W on the substrate mounting surface by controlling each element of the PM 1
b) A process of performing the process a) on the first number of the substrates W
c) A process of, after the process b), lifting the first ring ER with respect to the first ring mounting surface by the plurality of lifter pins 61 by controlling at least one lifting mechanism 63
d) A process of, in a state of the process c), performing first cleaning in the plasma processing chamber 10 by first plasma generated from the first cleaning gas by controlling each element of the PM 1
e) A process of performing the process a) on the second number of the substrates W, the second number being larger than the first number
f) A process of, after the process e), mounting the cleaning substrate W′ on the substrate mounting surface by controlling each element of the substrate processing system 50, and lifting the first ring ER with respect to the first ring mounting surface by the plurality of lifter pins 61 by controlling at least one lifting mechanism 63
g) A process of, in a state of the process f), performing second cleaning in the plasma processing chamber 10 by second plasma generated from a second cleaning gas by controlling each element of the PM 1
h) A process of transferring the first ring ER from the plasma processing chamber 10 to the accommodation apparatus 52 to replace the first ring ER by controlling each element of the substrate processing system 50

Further, in the embodiment, the first cleaning is performed in a state where the substrate mounting surface is exposed (that is, without a wafer), and the first cleaning gas includes at least one selected from the group consisting of an O₂ gas, a CO gas, a CO₂ gas, a COS gas, an N₂ gas, and an H₂ gas. The second cleaning gas includes a halogen-containing gas. The halogen-containing gas includes a CF-containing gas, an NF₃ gas, a Cl₂ gas, or an HBr gas. The CF-containing gas includes a CF₄ gas. Further, in the embodiment, the cleaning substrate W′ has an outer diameter smaller than the inner diameter of the first ring ER. The first ring ER is lifted to a first height in the process c), and is lifted to a second height different from the first height in the process f).

Further, in the embodiment, the controller 2 is configured to control each element of the substrate processing system 50 to further perform the following processes.
i) A process of performing the process a) on the third number of the substrates W, the third number being larger than the second number
j) A process of, after the process i), mounting the cleaning substrate W′ on the substrate mounting surface by controlling each element of the substrate processing system 50, and lifting the second ring CR with respect to the second ring mounting surface by the lifter pins 61 by controlling at least one lifting mechanism 63
k) A process of, in a state of the process j), performing third cleaning in the plasma processing chamber 10 by third plasma generated from a third cleaning gas by controlling each element of the PM 1
l) A process of transferring the second ring CR from the plasma processing chamber 10 to the accommodation apparatus 52 to replace the second ring CR by controlling each element of the substrate processing system 50

Further, in the embodiment, the controller 2 may be configured to control each element of the substrate processing system 50 to perform the following processes.
i) A process of performing the process a) on the third number of the substrates W, the third number being larger than the second number
j) A process of, after the process i), mounting the cleaning substrate W′ on the substrate mounting surface by controlling each element of the substrate processing system 50, and lifting the first ring ER with respect to the first ring mounting surface by the upper portion 610 of the lifter pin 61 by controlling at least one lifting mechanism 63 and lifting the second ring CR with respect to the second ring mounting surface by the lower portion 611 of the lifter pin 61 by controlling at least one lifting mechanism 63
k) A process of, in a state of the process j), performing third cleaning in the plasma processing chamber by third plasma generated from a third cleaning gas by controlling each element of the PM 1
l) A process of transferring the first ring ER and the second ring CR from the plasma processing chamber 10 to the accommodation apparatus 52 to replace the first ring ER and the second ring CR

Further, in the embodiment, the third cleaning gas is the same as the second cleaning gas.

Further, in the embodiment described above, the dummy substrate W′is accommodated in the accommodation apparatus 52 different from the VTM 51. On the other hand, the disclosed technology is not limited thereto. As another form, the dummy substrate W′ may be accommodated in a space provided in the VTM 51. Further, the edge ring ER for replacement may be accommodated in the space. Alternatively, the dummy substrate W′ may be accommodated in a container such as a FOUP connected to the load port 55.

Further, in the embodiment described above, the PM 1 that performs the processing on the substrate W using plasma has been described as an example. On the other hand, the disclosed technology is not limited thereto. As long as the apparatus performs processing on the substrate W, such as film formation or heat treatment, the disclosed technology can also be applied to an apparatus that does not use plasma.

Further, in the embodiment described above, capacitively-coupled plasma has been described as an example of a plasma source used for the PM 1. On the other hand, the plasma source is not limited thereto. Examples of the plasma source other than the capacitively coupled plasma include an inductively coupled plasma (ICP), a microwave excited surface wave plasma (SWP), an electron cyclotron resonance plasma (ECP), and a helicon wave excited plasma (HWP). Microwaves used for microwave excited surface wave plasma (SWP) are an example of electromagnetic waves.

It shall be understood that the embodiments disclosed herein are illustrative and are not restrictive in all aspects. Indeed, the above-described embodiments can be implemented in various forms. The embodiments described above may be omitted, replaced, or modified in various forms without departing from the scope and spirit of the appended claims.

Further, the following appendixes will be further disclosed with respect to the above-described embodiment.

### Appendix 1

A substrate processing apparatus including:
a processing container;
a stage that is provided in the processing container and has a first mounting surface on which a substrate is placed and a second mounting surface surrounding an outer periphery of the first mounting surface;
an edge ring that is configured to be placed on the second mounting surface;
a lifter that is configured to lift and lower the edge ring with respect to the second mounting surface; and
a controller,
in which the controller is configured to perform:
   a process a) of performing plasma processing on the substrate placed on the first mounting surface;
   a process b) of, each time the process a) is performed on a predetermined first number of the substrates, controlling the lifter to separate the edge ring from the second mounting surface and performing first cleaning of the inside of the processing container; and
   a process c) of, before replacing the edge ring, controlling the lifter to separate the edge ring from the second mounting surface and performing second cleaning of the inside of the processing container.

### Appendix 2

The substrate processing apparatus according to Appendix 1,
in which a processing condition in the second cleaning is obtained by changing at least one parameter from a processing condition in the first cleaning.

### Appendix 3

The substrate processing apparatus according to Appendix 2,
in which processing conditions in the first cleaning and the second cleaning include at least one parameter selected from the parameter group consisting of a type of a gas, a ratio of gas flow rates, a gas flow rate, a pressure, bias power, plasma generation power, a temperature of the stage, and a cleaning time.

### Appendix 4

The substrate processing apparatus according to any one of Appendixes 1 to 3,
in which plasma generation power supplied in the second cleaning is higher than plasma generation power supplied in the first cleaning.

### Appendix 5

The substrate processing apparatus according to any one of Appendixes 1 to 4,
in which the second cleaning is performed with bias power higher than bias power in the first cleaning.

### Appendix 6

The substrate processing apparatus according to any one of Appendixes 1 to 5,
in which bias power is not supplied in the first cleaning, and bias power is supplied in the second cleaning.

### Appendix 7

The substrate processing apparatus according to any one of Appendixes 1 to 6,
in which the second cleaning is performed at a pressure higher than a pressure in the first cleaning.

### Appendix 8

The substrate processing apparatus according to any one of Appendixes 1 to 7,
in which a temperature of the stage in the second cleaning is higher than a temperature of the stage in the first cleaning.

### Appendix 9

The substrate processing apparatus according to any one of Appendixes 1 to 8,
in which the cleaning time in the second cleaning is longer than the cleaning time in the first cleaning.

### Appendix 10

The substrate processing apparatus according to any one of Appendixes 1 to 9,
in which the second cleaning is performed in a state where a dummy substrate is placed on the first mounting surface.

### Appendix 11

The substrate processing apparatus according to Appendix 10,

in which the controller is configured to further perform a process of unloading the edge ring after the second cleaning is performed, and

the dummy substrate is placed on the first mounting surface until unloading of the edge ring is ended by the process d).

### Appendix 12

The substrate processing apparatus according to Appendix 11,
in which the dummy substrate is placed on the first mounting surface until unloading of the edge ring is ended by the process d) and another edge ring is loaded into the processing container.

### Appendix 13

The substrate processing apparatus according to any one of Appendixes 1 to 12,
in which a height from the second mounting surface to the edge ring when the first cleaning is performed is different from a height from the second mounting surface to the edge ring when the second cleaning is performed.

### Appendix 14

The substrate processing apparatus according to any one of Appendixes 1 to 13,
in which the controller is configured to further perform:
   a process e) of performing third cleaning of the inside of the processing container in a state where the edge ring is placed on the second mounting surface, and
the process e) is performed each time the process a) is performed on a second number of the substrates, the second number being equal to or smaller than the first number.

### Appendix 15

The substrate processing apparatus according to any one of Appendixes 1 to 14,
in which a first electrode is embedded inside the stage corresponding to the first mounting surface,
a second electrode is embedded inside the stage corresponding to the second mounting surface,
the substrate is attracted onto the first mounting surface by an electrostatic force generated by a voltage applied to the first electrode,
the edge ring is attracted onto the second mounting surface by an electrostatic force generated by a voltage applied to the second electrode, and
the controller is configured to perform, before performing the process b) and the process c), electrostatic elimination processing on the edge ring at the same timing as electrostatic elimination processing performed on the substrate on which processing of the process a) is ended.

### Appendix 16

The substrate processing apparatus according to any one of Appendixes 1 to 15, further including:
a cover ring that is placed on a third mounting surface of the stage surrounding an outer periphery of the second mounting surface and is disposed to surround the edge ring placed on the second mounting surface,
in which the controller is configured to perform, in the process c), the second cleaning in a state where the cover ring is further separated from the third mounting surface by controlling the lifter, and
after the process c) is performed, the edge ring and the cover ring are replaced with another edge ring and another cover ring.

### Appendix 17

The substrate processing apparatus according to any one of Appendixes 1 to 16,
in which, in the first cleaning and the second cleaning, cleaning of the inside of the processing container is performed using plasma generated from a cleaning gas including at least one selected from the group consisting of an O₂ gas, a CO gas, a CO₂ gas, a COS gas, an N₂ gas, and an H₂ gas.

### Appendix 18

The substrate processing apparatus according to Appendix 17,
in which, in the second cleaning, a halogen-containing gas is further supplied into the processing container.

### Appendix 19

The substrate processing apparatus according to Appendix 18,
in which, in the first cleaning, a halogen-containing gas is further supplied into the processing container, and
a flow rate of the halogen-containing gas supplied into the processing container in the second cleaning is higher than a flow rate of the halogen-containing gas supplied into the processing container in the first cleaning.

### Appendix 20

The substrate processing apparatus according to Appendix 18 or 19,
in which the halogen-containing gas is a CF₄ gas, an NF₃ gas, a Cl₂ gas, or an HBr gas.

### Appendix 21

A substrate processing system including:
a vacuum transfer apparatus that is configured to transfer a substrate in a vacuum environment;
a substrate processing apparatus that is configured to process the substrate; and
an accommodation apparatus that is configured to accommodate a dummy substrate,
in which the substrate processing apparatus includes:
   a processing container;
   a stage that is provided in the processing container and has a first mounting surface on which the substrate is placed and a second mounting surface which surrounds an outer periphery of the first mounting surface and on which an edge ring is placed;
   an edge ring that is configured to be placed on the second mounting surface;
   a lifter that is configured to lift and lower the edge ring with respect to the second mounting surface; and
   a controller,
the controller is configured to perform:
   a process a) of performing plasma processing on a substrate placed on the first mounting surface;
   a process b) of, each time the process a) is performed on a predetermined first number of the substrates, controlling the lifter to separate the edge ring from the second mounting surface and performing first cleaning of the inside of the processing container; and
   a process c) of, before replacing the edge ring, controlling the lifter to separate the edge ring from the second mounting surface and performing second cleaning of the inside of the processing container, and
the second cleaning is performed in a state where the dummy substrate is transferred from the accommodation apparatus into the processing container and the dummy substrate is placed on the first mounting surface.

### Appendix 22

The substrate processing system according to Appendix 21,
in which the edge ring for replacement is further accommodated in the accommodation apparatus.

### Appendix 23

The substrate processing system according to Appendix 21 or 22,
in which a transfer apparatus configured to transfer the edge ring and the dummy substrate is provided in the vacuum transfer apparatus, and
the transfer apparatus is configured to simultaneously unload the edge ring and the dummy substrate from the processing container.

### Appendix 24

A cleaning method including:
a) performing plasma processing on a substrate placed on a first mounting surface of a stage provided in a processing container;
b) separating an edge ring from a second mounting surface of the stage by a lifter and performing first cleaning of the inside of the processing container, the edge ring being placed on the second mounting surface of the stage surrounding an outer periphery of the first mounting surface and being disposed to surround the substrate placed on the first mounting surface; and
c) separating, before replacing the edge ring, the edge ring from the second mounting surface and performing second cleaning of the inside of the processing container,
in which the b) is performed each time the a) is performed on a predetermined first number of the substrates.

1. A substrate processing system comprising:
a vacuum transfer apparatus;
a plasma processing apparatus connected to the vacuum transfer apparatus;
a ring stocker; and
circuitry,
wherein the plasma processing apparatus includes:
a plasma processing chamber;
a stage disposed in the plasma processing chamber and having a substrate mounting surface, a first ring mounting surface, and a second ring mounting surface;
a first ring disposed to surround a substrate on the substrate mounting surface and including an inner annular portion and an outer annular portion, the inner annular portion of the first ring being mounted on the first ring mounting surface;
a second ring including an inner annular portion and an outer annular portion, the inner annular portion of the second ring being configured to support the outer annular portion of the first ring, the outer annular portion of the second ring being mounted on the second ring mounting surface, the inner annular portion of the second ring having a plurality of through-holes;
a plurality of lifter pins respectively aligned with the plurality of through-holes, each of the lifter pins including an upper portion and a lower portion, the upper portion being configured to support the first ring via a corresponding through-hole, the upper portion having a smaller horizontal dimension than the corresponding through-hole, the lower portion having a larger horizontal dimension than the corresponding through-hole; and
at least one actuator configured to move the plurality of lifter pins in a vertical direction, and
the circuitry is configured to:
a) control the plasma processing apparatus to perform plasma processing of the substrate that is disposed on the substrate mounting surface;
b) perform the a) on a first number of substrates;
c) control the plurality of lifter pins to lift, after the b), the first ring with respect to the first ring mounting surface;
d) control the plasma processing apparatus to perform, in a state of the c), first cleaning in the plasma processing chamber with first plasma generated from a first cleaning gas, the first cleaning being performed with the substrate mounting surface exposed, the first cleaning gas including at least one selected from the group consisting of an O₂ gas, a CO gas, a CO₂ gas, a COS gas, an N₂ gas, and an H₂ gas;
e) control the plasma processing apparatus to perform the a) on a second number of substrates, the second number being larger than the first number;
f) control the vacuum transfer apparatus to mount, after the e), a cleaning substrate on the substrate mounting surface and control the plurality of lifter pins to lift the first ring with respect to the first ring mounting surface;
g) control the plasma processing apparatus to perform, in a state of the f), second cleaning in the plasma processing chamber with second plasma generated from a second cleaning gas, the second cleaning gas including a halogen-containing gas; and
h) control the vacuum transfer apparatus to transfer the first ring from the plasma processing chamber to the ring stocker to replace the first ring.

2. The substrate processing system according to claim 1,
wherein the halogen-containing gas includes a CF-containing gas, an NF₃ gas, a Cl₂ gas, or an HBr gas.

3. The substrate processing system according to claim 2,
wherein the CF-containing gas includes a CF₄ gas.

4. The substrate processing system according to claim 1,
wherein the cleaning substrate has an outer diameter smaller than an inner diameter of the first ring.

5. The substrate processing system according to claim 1,
wherein the first ring is lifted to a first height in the c), and is lifted to a second height different from the first height in the f).

6. The substrate processing system according to claim 1,
wherein the circuitry is configured to:
i) control the plasma processing apparatus to perform the a) on a third number of substrates, the third number being larger than the second number;
j) control the vacuum transfer apparatus to mount, after the i), a cleaning substrate on the substrate mounting surface and control the plurality of lifter pins to lift the second ring with respect to the second ring mounting surface;
k) control the plasma processing apparatus to perform, in a state of the j), third cleaning in the plasma processing chamber with third plasma generated from a third cleaning gas; and
l) control the vacuum transfer apparatus to transfer the second ring from the plasma processing chamber to the ring stocker to replace the second ring.

7. The substrate processing system according to claim 1,
wherein the circuitry is configured to:
i) control the plasma processing apparatus to perform the a) on a third number of substrates, the third number being larger than the second number;
j) control the vacuum transfer apparatus to mount, after the i), a cleaning substrate on the substrate mounting surface and control the plurality of lifter pins to lift the first ring with respect to the first ring mounting surface with the upper portion of each of the lifter pins and lift the second ring with respect to the second ring mounting surface with a lower portion of each of the lifter pins;
k) performing, in a state of the j), third cleaning in the plasma processing chamber with third plasma generated from a third cleaning gas; and
l) transferring the first ring and the second ring from the plasma processing chamber to the ring stocker to replace the first ring and the second ring.

8. The substrate processing system according to claim 7,
wherein the third cleaning gas is the same as the second cleaning gas.

9. The substrate processing system according to claim 1,
wherein the plasma processing apparatus further includes at least one source radio frequency power source, and
the first plasma is generated with first source RF power from the at least one source RF power source, the second plasma is generated with second source RF power from the at least one source RF power source, and the second source RF power is higher than the first source RF power.

10. The substrate processing system according to claim 9,
wherein the plasma processing apparatus further includes:
at least one electrode disposed in the stage; and
at least one bias RF power source configured to supply first bias RF power to the at least one electrode in the first cleaning and supply second bias RF power higher than the first bias RF power to the at least one electrode in the second cleaning.

11. The substrate processing system according to claim 10,
wherein the first bias RF power has a zero power level.

12. The substrate processing system according to claim 9,
wherein the plasma processing apparatus further includes:
at least one electrode disposed in the stage; and
at least one voltage pulse generator configured to supply a sequence of a plurality of first voltage pulses to the at least one electrode in the first cleaning and supply a sequence of a plurality of second voltage pulses to the at least one electrode in the second cleaning,
the first voltage pulses have a first voltage level, and
the second voltage pulses have a second voltage level higher than the first voltage level.

13. The substrate processing system according to claim 12,
wherein the first voltage level has a zero voltage level.

14. The substrate processing system according to claim 1,
wherein the first cleaning is performed at a first pressure, and the second cleaning is performed at a second pressure higher than the first pressure.

15. The substrate processing system according to claim 1,
wherein the plasma processing apparatus further includes:
a temperature controller configured to maintain the stage at a first temperature during the first cleaning and maintain the stage at a second temperature higher than the first temperature during the second cleaning.

16. The substrate processing system according to claim 1,
wherein the first cleaning is performed for a first time, and the second cleaning is performed for a second time longer than the first time.

17. A substrate processing apparatus comprising:
a plasma processing chamber;
a stage disposed in the plasma processing chamber and having a substrate mounting surface and a ring mounting surface;
an edge ring mounted on the ring mounting surface to surround a substrate on the substrate mounting surface;
a lifter configured to lift and lower the edge ring with respect to the ring mounting surface with a plurality of lifter pins; and
circuitry,
wherein the circuitry is configured to:
a) control the plasma processing apparatus to perform plasma processing of the substrate that is disposed on the substrate mounting surface;
b) perform the a) on a first number of substrates;
c) control the plurality of lifter pins to lift, after the b), the edge ring with respect to the ring mounting surface;
d) control the plasma processing apparatus to perform, in a state of the c), first cleaning in the plasma processing chamber with first plasma generated from a first cleaning gas;
e) control the plasma processing apparatus to perform a) on a second number of substrates, the second number being larger than the first number;
f) control the plurality of lifter pins to lift, after the e), the edge ring with respect to the ring mounting surface; and
g) control the plasma processing apparatus to perform, in a state of the f), second cleaning in the plasma processing chamber with second plasma generated from a second cleaning gas.

18. The substrate processing apparatus according to claim 17,
wherein a condition for the second cleaning is different from a condition for the first cleaning.

19. The substrate processing apparatus according to claim 17,
wherein the first cleaning gas includes at least one selected from the group consisting of an O₂ gas, a CO gas, a CO₂ gas, a COS gas, an N₂ gas, and an H₂ gas, and the second cleaning gas includes a halogen-containing gas.

20. A cleaning method using a plasma processing apparatus, the plasma processing apparatus including:
a plasma processing chamber;
a stage disposed in the plasma processing chamber and having a substrate mounting surface and a ring mounting surface; and
an edge ring mounted on the ring mounting surface to surround a substrate on the substrate mounting surface, the cleaning method comprising:
a) performing plasma processing of the substrate disposed on the substrate mounting surface;
b) performing the a) on a first number of substrates;
c) lifting, after the b), the edge ring with respect to the ring mounting surface;
d) performing, in a state of the c), first cleaning in the plasma processing chamber with first plasma generated from a first cleaning gas;
e) performing the a) on a second number of substrates, the second number being larger than the first number;
f) lifting, after the e), the edge ring with respect to the ring mounting surface; and
g) performing, in a state of the f), second cleaning in the plasma processing chamber with second plasma generated from a second cleaning gas.
